(19) United States
(12) Patent Application Publication
(10) Pub. No.: US 2012/0132243 A1
(43) Pub. Date: May 31, 2012

(54) Thermoelectric Module with Improved Efficiency

(75) Inventors: Nathalie Caillault, Vourey (FR); Cédric Giroud, Voiron (FR); Joan Aymami, Grenoble (FR)

(73) Assignee: Schneider Electric Industries SAS, Rueil-Malmaison (FR)

(21) Appl. No.: 13/303,776

(22) Filed: Nov. 23, 2011

(30) Foreign Application Priority Data
Nov. 26, 2010 (FR) 10 04595

(51) Int. Cl. H01L 35/32; H01L 35/28

(52) U.S. Cl. 136/224; 136/200

(57) ABSTRACT

A thermoelectric module comprising a matrix comprising junctions having two N-type and P-type thermoelectric chips, said junctions being electrically connected to form an electric circuit. Flow of an electric current in the circuit heats one surface of the matrix by Peltier effect. Heating of one surface of the matrix makes an electric current flow by Seebeck effect. The module comprises a first group of junctions of two N-type and P-type thermoelectric chips exposed to a first operating temperature. A second group of junctions of two N-type and P-type thermoelectric chips is exposed to a second operating temperature. The second temperature is lower than the first temperature and the two groups of junctions are separated by a thermal insulator.

### BACKGROUND OF THE INVENTION

The invention relates to a thermoelectric module comprising a matrix comprising junctions having two thermoelectric chips of N type and P type, said junctions being electrically connected to form an electric circuit. Flow of an electric current in the circuit heats a surface of the matrix by Peltier effect. Heating of the surface of the matrix makes an electric current flow in the circuit by Seebeck effect.

### STATE OF THE PRIOR ART

The use of thermoelectric chips of N type and P type arranged together so as to create thermoelectric energy converters is known.

As represented in FIG. 1 and as described in Patent applications FR2775123 and EP1331674, the thermoelectric converter or module is designed to be secured between a bottom layer 130 and a top layer 140.

The thermoelectric converter or module M comprises a matrix composed of at least one column comprising an alternation of P-type and N-type thermoelectric chips 31 and 32. Two elements of the same type are thus separated by an element of the other type.

The chips are electrically connected in series by means of first and second contacts 11 and 21 respectively arranged on opposite surfaces of the chips. As is well shown in FIG. 1, each N-type electrode 31 is connected on one side via a first contact 11 to the neighbouring P-type electrode 32 by a conducting track 12 arranged on the bottom layer 130, and on the other side via a second contact 21 to its other neighbouring P-type electrode 32 by a conducting track 22 arranged on the top layer 140. In identical and quite obvious manner, each P-type electrode 32 is connected on one side via a first contact 11 to the neighbouring N-type electrode 31 by a track 12 on the bottom layer 130, and on the other side via a second contact 21 to its other neighbouring N-type electrode 31 by a track 22 on the top layer 140.

The small thickness and the rigidity of this component structure mean that the temperature difference at its terminals becomes small with time. If the temperature difference becomes small, the thermogenerator loses performance.

To preserve the desired temperature difference, the thermoelectric converter or module has to be associated with a heat exchange device. The heat exchange device can preferably comprise a base provided with heat radiation fins and a panel acting as heat exchange surface for the purposes of cooling or heating.

The presence of this heat exchange device considerably increases the volume of the product making the latter difficult to integrate in certain products.

Another solution as described in Patent application US2003042497 enables the efficiency of the product to be increased by astute management of the temperature gradient and by a new arrangement of the electrodes. The electrodes of the junctions are in fact arranged in the form of stacked thin layers. However, on account of its small thickness, this situation is subject to the same problem as previously.

### SUMMARY OF THE INVENTION

The object of the invention is therefore to remedy the drawbacks of the state of the art so as to propose a thermoelectric model with improved efficiency.

The module according to the invention comprises a first and second group of junctions separated from one another by a thermal insulator, the first group comprising at least one junction of two thermoelectric chips of N type and P type, and the second group comprising at least one junction of two thermoelectric chips of N type and P type, the first and second groups of junctions being respectively exposed to a first and a second temperature. The two N-type and P-type chips are of flattened shape to be stacked on an insulating substrate by deposition of thin layers on an insulating substrate. At least one N-type chip of a first junction of the first group is electrically connected with a P-type or N-type chip of a first junction of the second group.

According to a mode of development of the invention, at least one N-type chip of a first junction of the first group is connected in series with a P-type chip of a first junction of the second group to increase the voltage.

Preferably an N-type chip of a first junction of the first group is connected in series with a P-type chip of the first junction of the second group and a P-type chip of the first junction of the first group is connected in series with an N-type chip of a second junction of the second group.

According to another mode of development of the invention, an N-type chip of at least a first junction of the first group is connected in parallel with an N-type chip of at least a first junction of the second group, and a P-type chip of said at least a first junction of the first group is connected in parallel with a P-type chip to said at least a first junction of the second group to increase the current intensity.

Advantageously, the thermal insulator separating the two groups of junctions is air enabling the existing temperature difference between the first and second temperature to be maintained.

### BRIEF DESCRIPTION OF THE DRAWINGS

Other advantages and features will become more clearly apparent from the following description of particular embodiments of the invention, given as non-restrictive examples only and represented in the appended drawings in which:

FIG. 1 represents a schematic view of a thermoelectric module according to a known embodiment;

FIG. 2 represents a schematic view of a thermoelectric module according to a preferred embodiment of the invention;

FIG. 3 represents a schematic view of a thermoelectric module according to a second preferred embodiment of the invention.

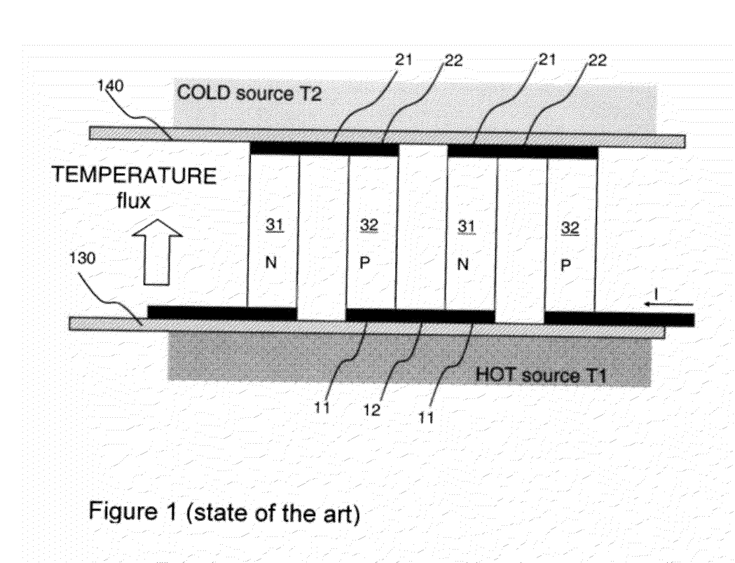

### DETAILED DESCRIPTION OF AN EMBODIMENT

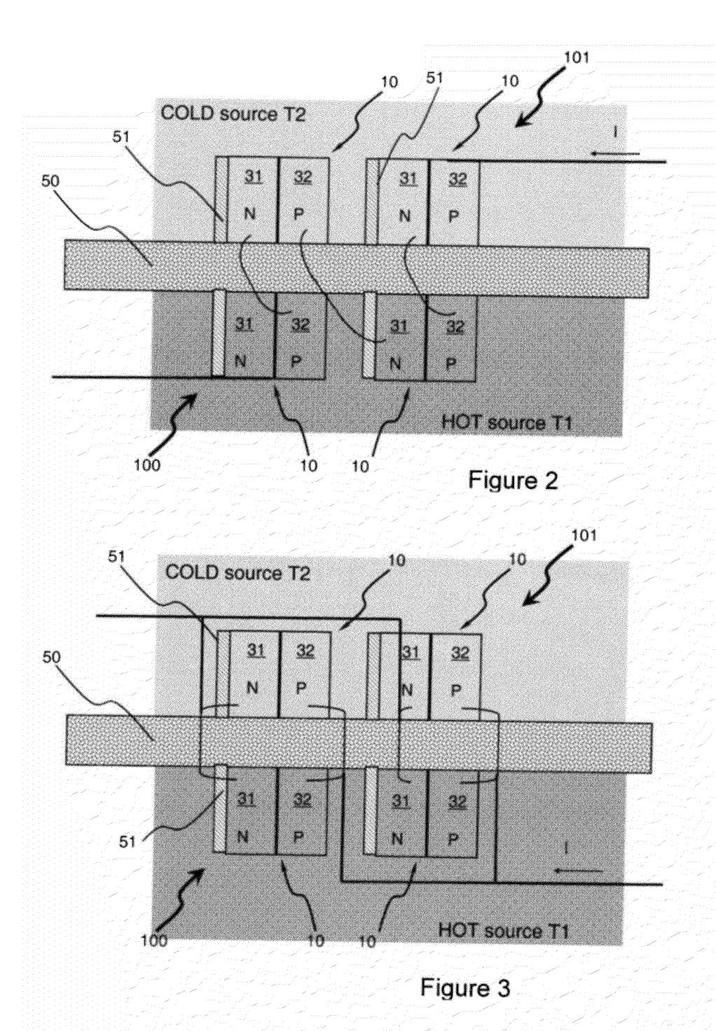

According to the embodiments as represented in FIGS. 2 and 3, the thermoelectric module comprises a matrix delineated by two surfaces and comprising junctions 10 respectively having two N-type and P-type thermoelectric chips 31, 32. Said junctions are electrically connected to form an electric circuit.

The junctions 10 are electrically connected to one another so that flow of an electric current I in a selected direction heats or cools one of the surfaces of the matrix by Peltier effect created at the level of the chips. Furthermore, heating or cooling of one of the surfaces of the matrix makes an electric current flow in a given direction by Seebeck effect created at the level of the chips.

According to the embodiments of the invention, the thermoelectric module comprises a first group 100 comprising at least one junction 10 of two N-type and P-type thermoelectric chips 31, 32. Said first group of junctions is exposed to a first operating temperature T1. A second group 101 comprises at least one junction 10 of two P-type and N-type thermoelectric chips 31, 3. The second group of junctions is exposed to a second operating temperature T2. The second temperature T2 is lower than the first temperature T1. As an example embodiment, the first temperature T1 can reach a value of −10° C. and the second temperature T2 can reach a value of 140° C.

The two groups of junctions are separated from one another by a thermal insulator 50 enabling the existing temperature difference between T1 and T2 to be maintained. As an example embodiment, the thermal insulator 50 separating the two groups of junctions 101, 101 is preferably air. According to alternative embodiments, the thermal insulator can be formed by an insulating ceramic having a base that is for example alumina or cordierite. The insulator can also be formed by an insulating polymer able to withstand the temperatures of use.

As an example embodiment as represented in FIGS. 2 and 3, each group of junctions 100, 101 respectively comprises two junctions 10. The number of junctions 10 and their connections (series and parallel) is determined according to the power to be supplied by the thermogenerator module.

According to a preferred embodiment of the invention as represented in FIG. 2, the thermoelectric module comprises at least one N-type chip 31 of a first junction 10 of the first group 100 connected in series with a P-type chip 32 of a first junction 10 of the second group 101. According to this embodiment, this configuration enables the voltage at the terminals of the thermoelectric module to be increased. For example purposes, an N-type chip 31 of the first junction 10 of the first group is connected in series with a P-type chip 32 of a first junction 10 of the second group 101. A P-type chip of the first junction 10 of the first group 100 is further connected in series with an N-type chip 31 of a second junction 10 of the second group 101.

According to a preferred embodiment of the invention as represented in FIG. 3, the thermoelectric module comprises an N-type chip 31 of at least a first junction 10 of the first group 101 connected in parallel with an N-type chip 31 of at least a first junction of the second group 101. A P-type chip 32 of said at least a first junction of the first group is further connected in parallel with a P-type chip 32 of said at least a first junction of the second. According to this embodiment, this configuration enables the current intensity to be increased.

According to an embodiment of the invention, the two N-type and P-type chips 31, 32 of the junction 10 are of flattened shape to be stacked on an insulating substrate 51.

The junctions 10 are preferably made by depositions of thin layers on an insulating substrate. The depositions can then in particular be made by physical vapor deposition (PVD). The depositions can also in particular be made by chemical vapor deposition (CVD). Finally the depositions of thin layers can be made by ink jet printing technique or by wet method deposition.

The junctions 10 are preferably achieved by lamination of thick layers on an insulating substrate.

1. A thermoelectric module comprising a matrix comprising junctions respectively having two N-type and P-type thermoelectric chips, said junctions being electrically connected to form an electric circuit in such a way that:
flow of an electric current in a selected direction heats or cools one of the surfaces of the matrix by Peltier effect created at the level of the chips;
heating or cooling of one of the surfaces of the matrix makes an electric current flow in a given direction due to a Seebeck effect created at the level of the chips;
a module comprising a first and second group of junctions separated from one another by a thermal insulator, the first group comprising at least one junction of two N-type and P-type thermoelectric chips and the second group comprising at least one junction of two N-type and P-type thermoelectric chips, the first and second groups of junctions being respectively exposed to a first and a second operating temperature,
the two N-type and P-type chips of a junction being of flattened shape to be stacked on an insulating substrate by deposition of thin layers on an insulating substrate;
at least one N-type chip of a first junction of the first group being electrically connected with a P-type or N-type chip of a first junction of the second group.

2. The thermoelectric module according to claim 1 wherein at least one N-type chip of a first junction of the first group is connected in series with a P-type chip of a first junction of the second group to increase the voltage.

3. The thermoelectric module according to claim 2 wherein an N-type chip of the first junction of the first group is connected in series with a P-type chip of the first junction of the second group and a P-type chip of the first junction of the first group is connected in series with an N-type chip of a second junction of the second group.

4. The thermoelectric module according to claim 1 wherein an N-type chip of at least a first junction of the first group is connected in parallel with an N-type chip of at least a first junction of the second group and said at least a first junction of the first group is connected in parallel with a P-type chip of said at least a first junction of the second group to increase the current intensity.

5. The thermoelectric module according to claim 1, wherein the thermal insulator separating the two groups of junctions enables the existing temperature difference between the first and second operating temperature to be preserved.
